(19) United States
(12) Patent Application Publication
(10) Pub. No.: US 2025/0317213 A1
(43) Pub. Date: Oct. 9, 2025

(54) TRANSMITTER AND RECEIVER CROSSTALK SHIELDING

(71) Applicant: Idea Sistemas Eletronicôs LTDA S.A., Campinas (BR)

(72) Inventors: Leandro Andrade Couto FONSECA, Campinas (BR); Leandro Torres ZANVETTOR, Campinas (BR); Alexandre Passos FREITAS, Campinas (BR); Wender Gonçalves DANIEL, Campinas (BR); Roddy Elky Ramos GONZALES, Campinas (BR); Luis Henrique HECKER DE CARVALHO, Campinas (BR); Leandro MATIOLLI MACHADO, Campinas (BR)

(21) Appl. No.: 19/088,163

(22) Filed: Mar. 24, 2025

Related U.S. Application Data
(60) Provisional application No. 63/575,578, filed on Apr. 5, 2024.

(51) Int. Cl. H04B 10/58; H03F 3/45; H04B 10/40; H05K 1/18

(52) U.S. Cl. CPC H04B 10/58; H03F 3/45071; H04B 10/40; H05K 1/181

(57) ABSTRACT

In some implementations, an optical device includes a transmitter, wherein the transmitter includes a set of opto-electric modulators disposed on a first section of a photonic integrated circuit (PIC), and wherein the transmitter includes a set of transmit (Tx) radio frequency (RF) electrical traces connected to the set of opto-electric modulators, the set of Tx RF traces including a first ground; a receiver, wherein the receiver is associated with a set of photodiodes, a set of trans-impedance amplifier (TIAs), and a set of receive (Rx) RF traces, wherein the set of RF traces is disposed on a second section of the PIC, the set of Rx RF traces including a second ground separate from the first ground, a transmitter shield that is electrically connected to the first ground and includes a set of fingers on the PIC; and a receiver shield partially on the PIC.

### CROSS-REFERENCE TO RELATED APPLICATION

This Patent Application claims priority to U.S. Provisional Patent Application No. 63/575,578, filed on Apr. 5, 2024, and entitled “TRANSMITTER AND RECEIVER SHIELDING FOR CROSSTALK REDUCTION.” The disclosure of the prior application is considered part of and is incorporated by reference into this Patent Application.

### TECHNICAL FIELD

The present disclosure relates generally to optical transceivers, and to transmitter and receiver crosstalk shielding.

### BACKGROUND

An optical device, such as an optical transceiver, may include multiple channels, such as a set of transmit channels and/or a set of receive channels. Crosstalk may occur when a first signal in a first channel couples into a second channel and causes a perturbation to a second signal in the second channel. For example, transmitter-to-transmitter (Tx-to-Tx) crosstalk may occur when a first transmit signal couples from a first channel to a second channel to perturb a second transmit signal. Similarly, transmitter-to-receiver (Tx-to-Rx) crosstalk may occur when a transmit signal couples from a first channel to a second channel to perturb a receive signal.

### SUMMARY

In some implementations, an optical device includes a transmitter, wherein the

transmitter includes a set of opto-electric modulators disposed on a first section of a photonic integrated circuit (PIC), and wherein the transmitter includes a set of transmit (Tx) radio frequency (RF) electrical traces connected to the set of opto-electric modulators, the set of Tx RF traces including a first ground; a receiver, wherein the receiver is associated with a set of photodiodes, a set of trans-impedance amplifier (TIAs), and a set of receive (Rx) RF traces, wherein the set of RF traces is disposed on a second section of the PIC, the set of Rx RF traces including a second ground separate from the first ground, a transmitter shield that is electrically connected to the first ground and includes a set of fingers on the PIC; and a receiver shield partially on the PIC.

In some implementations, an optical device includes a transmitter with a transmitter shield, wherein the transmitter includes a set of opto-electric modulators disposed on a transmitter PIC, wherein the transmitter includes a set of Tx RF electrical traces connected to the set of opto-electric modulators, the set of Tx RF traces including a first ground, and wherein the transmitter shield includes a set of fingers on the PIC and wherein the transmitter shield is electrically connected to the first ground.

In some implementations, an optical device includes a transmitter, comprising: a set of opto-electric modulators disposed on a first PIC, a set of Tx RF electrical traces connected to the set of opto-electric modulators, the set of Tx RF traces including a first ground; a receiver, comprising: a set of Rx RF traces disposed on a second PIC, the set of Rx RF traces including a second ground separate from the first ground; a transmitter shield on the first PIC and electrically connected to the first ground; and a receiver shield partially on the second PIC and electrically connected to the second ground.

### BRIEF DESCRIPTION OF THE DRAWINGS

FIG. 1 is a diagram of an example optical device associated with transmitter and receiver crosstalk shielding.

FIGS. 2A-2B are diagrams of example implementations 200/200′ associated with transmitter shielding.

FIGS. 3A-3B are diagrams of an example implementation associated with receiver shielding.

FIGS. 4A-4B are diagrams of crosstalk suppression associated with receiver shielding.

### DETAILED DESCRIPTION

The following detailed description of example implementations refers to the accompanying drawings. The same reference numbers in different drawings may identify the same or similar elements.

An optical device, such as an optical transceiver, may include a transmitter with a set of transmit channels and a receiver with a set of receive channels. The optical transmitter may include a Mach-Zehnder modulator (MZM), which may include a set of channels to modulate an optical signal with information. The optical receiver may include a set of photodiodes and radio frequency (RF) amplifiers to demodulate and obtain information being conveyed by an optical signal. In other words, one or more optical transmitters and one or more optical receivers may be packaged into a single package. In increasingly dense optical communications systems, such a package may be increasingly miniaturized, resulting in the optical transmitter and the optical receiver being positioned proximate to each other.

When channels are proximate to each other, electromagnetic energy coupling can perturb a signal in one or both channels. For example, a first signal in a first transmitter channel (e.g., of a first MZM) may couple to a second channel (e.g., of the first MZM or a second MZM) and perturb a second signal. In this case, the transmitter-to-transmitter (Tx-to-Tx) crosstalk may result in degraded transmitter operation. Similarly, a first signal in a transmitter channel may couple to a receiver channel and perturb a second signal in the receiver channel. In this case, the transmitter-to-receiver (Tx-to-Rx) crosstalk may result in degraded receiver operation.

Some optical devices may be configured with modulators that have less than a configured leakage of energy (e.g., from transmit channels), which may limit crosstalk. However, this may limit which modulators can be used for an optical device. Additionally, some modulators with relatively low levels of field leakage may be relatively large, have relatively few channels, have relatively low data rates, or other issues that may prevent inclusion in some optical communications systems. Another technique to avoid crosstalk is to position transmit channels with as much separation as possible and/or to position a transmitter at least a threshold distance from a receiver. However, suppressing crosstalk by distancing channels from each other may prevent miniaturization of optical communications systems for increasingly dense networks and increasingly high data rates.

Some implementations described herein may provide an optical device with a transmitter shield and/or a receiver shield. For example, some implementations may include a transmitter shield that is positioned within an apparatus package to suppress Tx-to-Tx crosstalk and/or Tx-to-Rx crosstalk. Additionally, or alternatively, some implementations may include a receiver shield that is positioned within an apparatus package to suppress Tx-to-Rx crosstalk. In some implementations, a transmitter shield and/or a receiver shield may include a metallized glass or metallized ceramic structure that suppresses electromagnetic coupling between channels to reduce a level of crosstalk between the channels. In this way, an optical device can provide multi-channel functionality with improved performance, such as with reduced error rates, improved signal-to-noise ratios (SNRs), or improved data rates, among other examples.

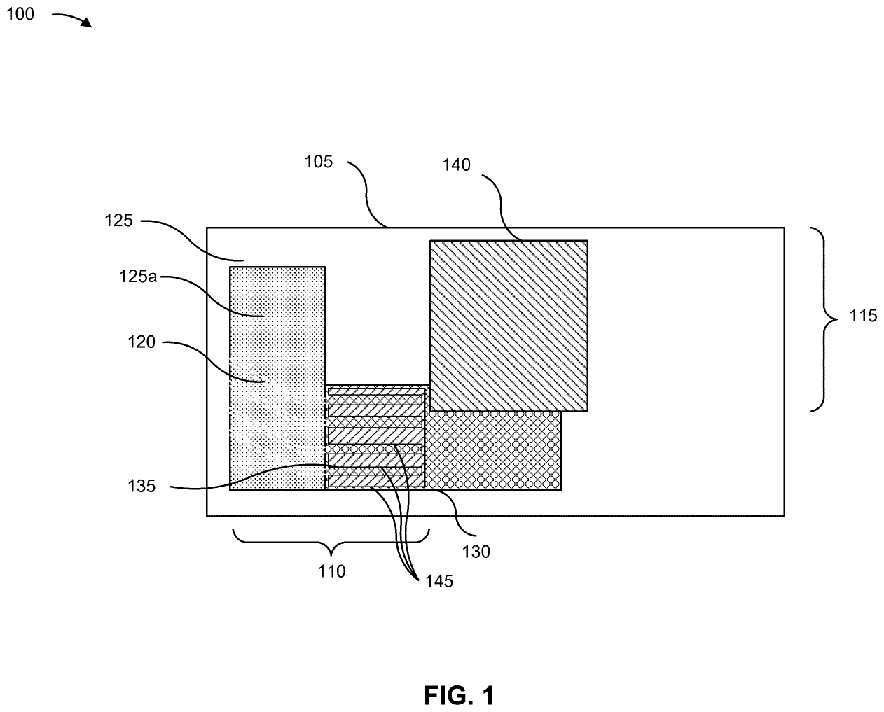

FIG. 1 is a diagram of an example optical device 100 associated with transmitter and receiver crosstalk shielding. As shown in FIG. 1, example optical device 100 includes a device package 105, a transmitter region 110 with a set of components to form a transmitter, and a receiver region 115 with a set of components to form a receiver.

The transmitter region 110 may include a set of transmitter RF traces 120 (e.g., a set of radio frequency (RF) ground-signal-ground (GSG) traces) disposed on a non-conductive package surface 125. The non-conductive package surface 125 may have a metallization layer 125a disposed thereon, which is patterned to form the set of transmitter RF traces 120. The transmitter region 110 may include at least a portion of a photonic integrated circuit (PIC) 130. The transmitter region 110 may include one or more opto-electric modulators, Mach-Zehnder modulators (MZMs), laser sources, traces, waveguides, taps, filters, splitters, combiners, interconnects, thermal management elements, ground elements, or other components (not shown) disposed in the transmitter region 110 and/or on or in the PIC 130. In one example of an optical transceiver, the transmitter region 110 includes a set of 4 MZMs (e.g., 4 travelling wave MZMs corresponding to an X modulation, a Y modulation, an in-phase (I) modulation, and a quadrature (Q) modulation) for modulating information onto a set of transmit channels. In this case, each MZM may be bracketed by a pair of fingers 145 to reduce cross talk between the MZMs and/or from the MZMs to the receiver region 115. In another example, there may be another quantity of MZMs, such as 2 or more MZMs, 4 or more MZMs, or 8 or more MZMs, among other examples. The fingers 145 may be connected to form a fork-like shape and may connect to an RF ground of the MZMs (e.g., via wire bondings or another type of connection, as described in more detail herein) or to an RF ground of the transmit region 110 to prevent propagation of electromagnetic interference.

The receiver region 115 may include one or more receiver RF traces (e.g., a set of RF GSG traces), photodiodes, trans-impedance amplifiers (TIAs), waveguides, taps, filters, splitters, combiners, interconnects, thermal management elements, ground elements, or other components (not shown) disposed in the receiver region 115 and/or on or in the PIC 130 or another substrate. In one example, the optical transceiver may include a dual-polarization coherent receiver with 4 channels, each of which includes a respective TIA and a respective photodiode. The photodiodes receive an optical signal (e.g., from one or more other components, such as one or more filters, splitters, combiners, or interconnects) and generates an electrical signal corresponding to the optical signal. The TIA amplifies a current signal of the electrical signal and converts the current signal to a voltage signal for further processing. The receiver RF traces convey electrical signals between the photodiodes and the TIA (e.g., the current signal) and conveys electrical signals between the TIAs and other components (e.g., processing components that may use the voltage signals outputted by the TIAs). As a result of the gain provided by the TIAs, any field leakage at the TIAs can cause a relatively large amount of noise in a signal output. Accordingly, and as described in more detail herein, suppressing field leakage to the TIAs can result in a significant reduction in noise and a corresponding significant improvement in performance.

In some implementations, the receiver region 115 may be associated with a first portion or section of the PIC 130 and the transmitter region 110 may be associated with a second portion or section of the PIC 130. In other words, the optical device 100 may include a transmitter and receiver formed on or in the same PIC 130, as shown. In some implementations, the optical device 100 may include multiple PICs 130, such as a first PIC 130 that is associated with the transmitter region 110 (e.g., a transmitter PIC) and a second PIC 130 that is associated with the receiver region 115 (e.g., a receiver PIC). In some implementations, the first PIC 130 and the second PIC 130 may be disposed on a common (single) chip substrate. In some implementations, the transmitter region 110 and the receiver region 115 are disposed in a common package or housing of the optical device 100. For example, the optical device 100 may include a ceramic package (e.g., with one or more metallized structures, such as a package that includes the non-conductive package surface 125 onto which the metallization 125a is disposed) that houses the transmitter region 110 and the receiver region 115 (and the components thereof).

In some implementations, the optical device 100 may include a transmitter shield 135 or a receiver shield 140, among other examples, as described in more detail herein. For example, the example optical device 100 may include a transmitter shield 135 that is electrically connected to a ground associated with the set of transmitter traces 120. The transmitter shield 135 may include one or more transmitter shielding elements that are disposed over, around, or proximate to elements of the transmitter region 110 and/or the transmitter thereof. For example, the transmitter shield 135 may include a set of fingers 145 that are disposed on a portion of the PIC 130. The transmitter shield 135 may modify a field distribution within a package or housing of the optical device 100 to reduce crosstalk. For example, the set of fingers 145 may constrain electromagnetic energy propagation between transmitter channels or between a transmitter channel and a receiver channel, such that electromagnetic energy couples to the set of fingers 145 and is grounded, rather than coupling from a particular channel to other channels.

Additionally, or alternatively, the optical device 100 may include a receiver shield 140 that is electrically connected to a ground associated with a set of receiver traces of the receiver region 115. For example, the receiver shield 140 may include a cover structure that covers a portion of the receiver region 115 and/or a receiver thereof (e.g., a set of TIAs and/or photodiodes of the receiver region 115). The receiver shield 140 may modify a field distribution within a package or housing of the optical device 100 to reduce crosstalk. For example, the receiver shield 140 may cause electromagnetic energy (e.g., that propagates from a transmitter channel to a receiver channel) to couple to a metallized section of the receiver shield 140 (e.g., which is grounded to cause the electromagnetic energy to be grounded rather than couple into a receiver channel). In some implementations the receiver shield 140 can be connected to a first ground and the transmitter shield 135 can be connected to a second ground. Depending on the transmitter and receiver design in a transceiver, the RF ground and one or more DC grounds can be shorted or isolated. Both the transmitter shield 135 and receiver shield 140 can have better shielding performance when grounded to an RF ground of the transmitter region 110 or the receiver region 115. In a configuration of a transceiver with a shared RF ground between transmitter and receiver circuits, the transmitter shield 135 and the receiver shield 140 can be grounded to a same shared ground. In another configuration of a non-shared ground between a transmitter region 110 and a receiver region 115, the transmitter shield 135 can be grounded to the a transmitter ground, while the receiver shield 140 can be grounded to a receiver ground. in some implementations, the receiver shield 140 may be connected to a first set of bondwires that ground the receiver shield 140, and the transmitter shield 135 may be connected to a second set of bondwires that ground the transmitter shield 135, such that a ground of the receiver shield 140 is internally isolated from a ground of the transmitter shield 135 (e.g., the grounds are isolated from each other within a package or housing of the optical device 100, but may connect outside the package or housing of the optical device 100). In this way, by avoiding a connection between the receiver shield 140 and the transmitter shield 135 within the optical device 100, the optical device 100 may experience reduced current leakage between transmit channels and receive channels.

As indicated above, FIG. 1 is provided as an example. Other examples may differ from what is described with regard to FIG. 1.

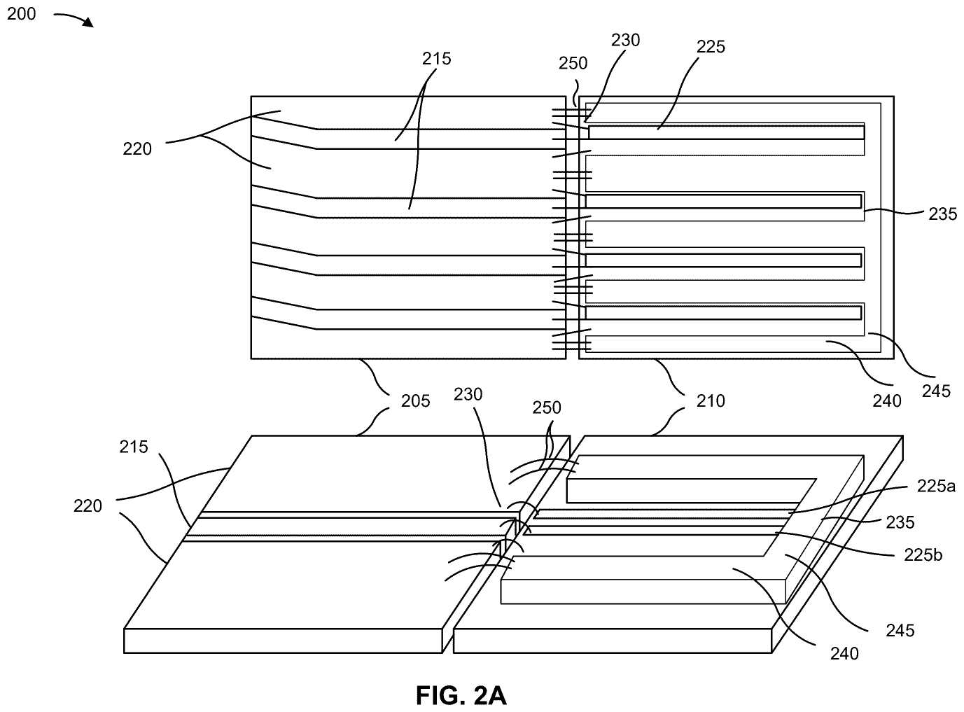

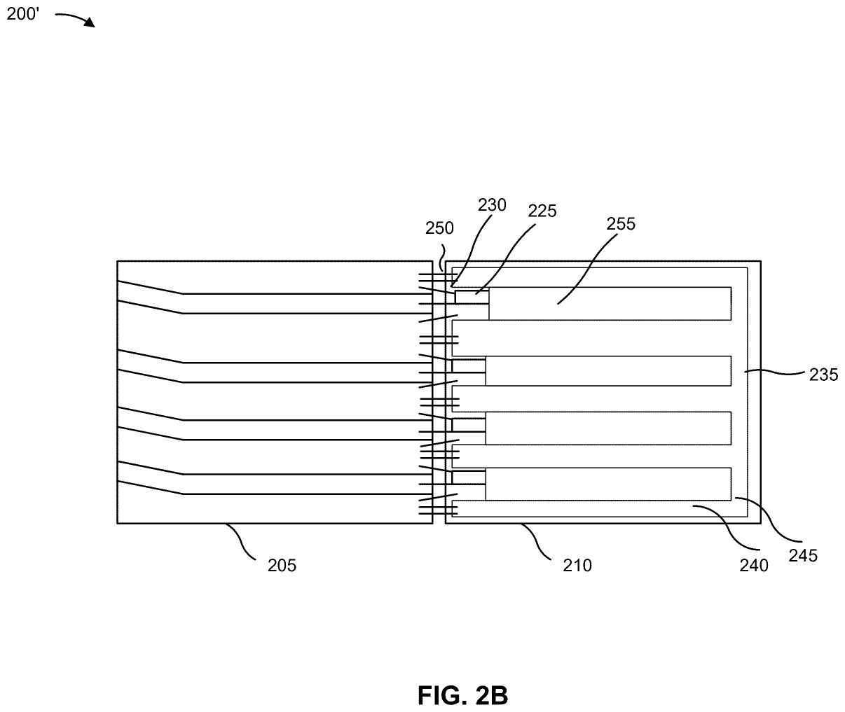

FIGS. 2A-2B are diagrams of example implementations 200/200′ associated with transmitter shielding. As shown in FIGS. 2A-2B, example implementations 200/200′ include a metallization layer 205 and a PIC 210. The metallization layer 205 includes a set of signal traces 215 that are disposed between grounded sections 220 (e.g., ground traces) of the metallization layer 205. The PIC 210 includes a set of MZMs 225 (or another type of opto-electric modulator) that are connected to the ground sections 220 and/or the signal traces 215 via a set of bonding wires 230. For example, an MZM 225 may include a first path 225a (e.g., an RF ground) that connects to a ground section 220 via a first bonding wire 230 and a second path 225b (e.g., an RF signal) that connects to a signal trace 215 via a second bonding wire 230. A transmitter shield 235 may be disposed on the PIC 210. The transmitter shield 235 may include a set of fingers 240 and an interconnect bar 245. The interconnect bar 245 may be at an interface between the set of signal traces 215 and the PIC 210, and the fingers 240 may extend orthogonal to the interconnect bar 245 and parallel to the MZMs 225. In another configuration, an interconnect bar may be disposed an another end of the PIC 210, proximate to connections with the bonding wires 250. Each finger 240 may be disposed parallel to the MZMs 225, and the interconnect bar 245 may be disposed orthogonal to the MZMs 225 and may electrically and mechanically connect the fingers 240. In some implementations, pairs of fingers 240 may surround an MZM 225, such that each MZM 225 is bracketed by a pair of fingers 240. In some implementations, the interconnect bar 245 may at least partially cross over one or more MZMs 225 of the set of MZMs 225. In some implementations, the transmitter shield 235 may be disposed above MZM termination loads of the MZMs 225, such that the transmitter shield 235 covers a region in between MZM RF traces of the MZMs 225.

A finger 240 may be electrically connected (e.g., grounded) to a grounded section 220 of the metallization layer 205 via a set of bonding wires 250. In other words, the transmitter shield 235 is attached to the PIC 210, but is grounded via the set of bonding wires 250 and the grounded section 220 of the metallization layer 205 (e.g., of a package that includes the PIC 210). By electrically connecting the transmitter shield 235 to an RF package ground, the transmitter shield 235 can provide crosstalk suppression for the MZM 225. As shown in FIG. 2B, and in example 200′, a transmit shield cover 255 may be disposed over an MZM 225. For example, a transmit shield cover 255 may bridge at least a portion of a gap between pairs of fingers 240 over an MZM 225. In some implementations, multiple transmit shield covers 255 may be attached to the transmitter shield 235 to cover multiple gaps between multiple pairs of fingers 240. Additionally, or alternatively, a single (e.g., monolithic) transmit shield cover 255 may cover multiple gaps between multiple pairs of fingers 240.

In some implementations, the set of fingers 240 may be positioned based on a position of an first path 225a of the MZMs 225 and/or a position of second path 225b of the MZMs 225. For example, the set of fingers 240 may be asymmetrically arranged, such that each finger 240 is closer to a corresponding first path 225a than to a corresponding second path 225b. This may reduce a perturbation to an MZM impedance relative to having the fingers positioned closer to the signal paths than to the RF grounds. In some implementations, different fingers may have different widths. For example, the inner fingers may be wider than the other fingers. In some implementations, the set of fingers 250 may fill or cover up at least a threshold portion of a gap between adjacent MZM lanes of the MZMs 225, thereby reducing field leakage between pairs of MZMs. As shown, the set of fingers 240 may cover or partially cover an end of a travelling wave RF lane of an MZM, which is a region at which there may be resistive load for impedance matching and where field leakage may occur. Accordingly, the interconnect bar 245 of the fingers 240 may provide crosstalk reduction by suppressing MZM field leakage.

In some implementations, the transmitter shield 235 is formed from a particular type of material. For example, the transmitter shield 235 may include a monolithic metal material or a coated metal material, such as a glass structure (e.g., borosilicate glass) or a ceramic structure (e.g., aluminum nitride) that is metallized using a metallization process. Use of a glass or ceramic structure for the transmitter shield 235 may provide mechanical properties similar to those of the PIC 210, which may also have a glass material or ceramic material, thereby improving manufacturability, durability, and/or thermal performance, among other examples. The transmitter shield 235, including a metal material, may provide a barrier to or reduction in crosstalk as well as a reduction in field leakage to a package that includes the optical device with the transmitter shield 235. The reduction in field leakage occurs as a result of electric fields from MZM lanes having a ground in relatively close proximity. Further, the transmitter shield 235 may be designed to reduce or minimize an impedance change caused to an optical device, thereby avoiding performance degradation from the presence of crosstalk suppression shielding. The transmitter shield 235 may be metallized on one or more surfaces. For example, a metallization element (e.g., a layer on a non-conductive surface or a monolithic metal structure) may be present on one or more sides of the fingers 240 (e.g., sides adjacent to MZMs 225) or a top surface of the fingers 240. Metallized surfaces (e.g., metallization on a non-conductive substrate) of the transmitter shield 235 may provide impedance change reduction relative to a monolithic metal structure. Additionally, or alternatively, metallization may be present on sides or a top surface of the interconnect bar 245.

In some implementations, the transmitter shield 235 may be formed from a metallized glass structure that is manufactured using a physical vapor deposition process. For example, the metallized glass structure may include a glass surface onto which one or more layers of metal are deposited using physical vapor deposition. In this case, the one or more layers of metal may include a titanium layer, a gold layer, or another layer. The titanium layer may be an approximately 20 nanometer (nm) layer that is deposited on the glass, and the gold layer may be deposited onto the titanium layer. This may improve adhesion of the gold layer relative to depositing the gold layer directly onto the glass layer. By manufacturing the transmitter shield 235 from a glass (or other substrate) with a metal deposition layer, the transmitter shield 235 may improve mechanical and/or thermal interaction with the PIC 210, improve manufacturability, and/or reduce impedance relative to a metal-only transmitter shield 235. In some implementations, the transmitter shield 235 is shaped and/or positioned to avoid impedance changes to the PIC 210 (and components thereon or therein).

In some implementations, the transmitter shield 235 may be attached to another component, such as the PIC 210. For example, the transmitter shield 235 may attach to the PIC 210 using glue, adhesive, mechanical attachment, or another attachment type. For example, the transmitter shield 235 may be attached to the PIC 210 using a non-conductive, ultraviolet fast-curable adhesive that can adhere glass (e.g., a substrate of the transmitter shield 235) to metal (e.g., a surface of the PIC 210).

As indicated above, FIGS. 2A-2B are provided as an example. Other examples may differ from what is described with regard to FIGS. 2A-2B.

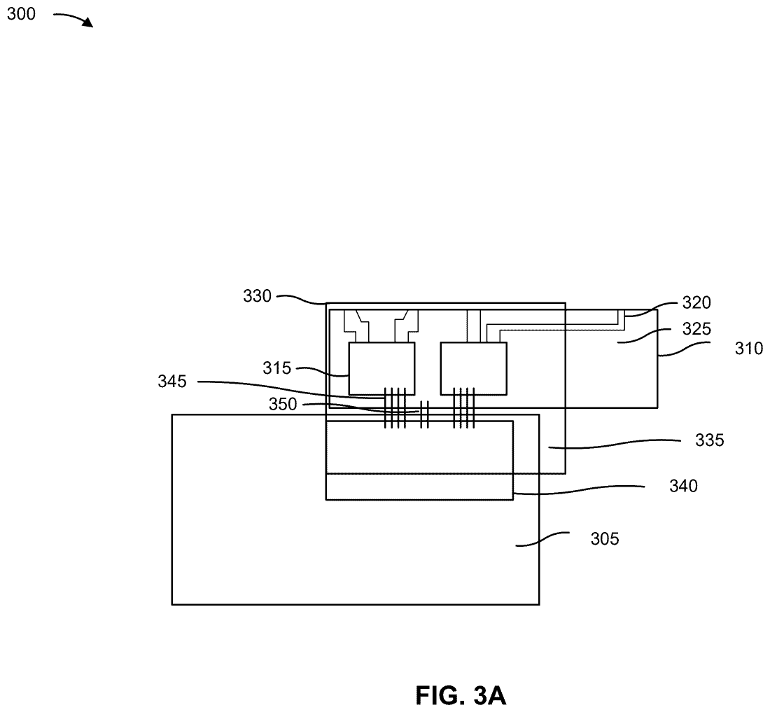

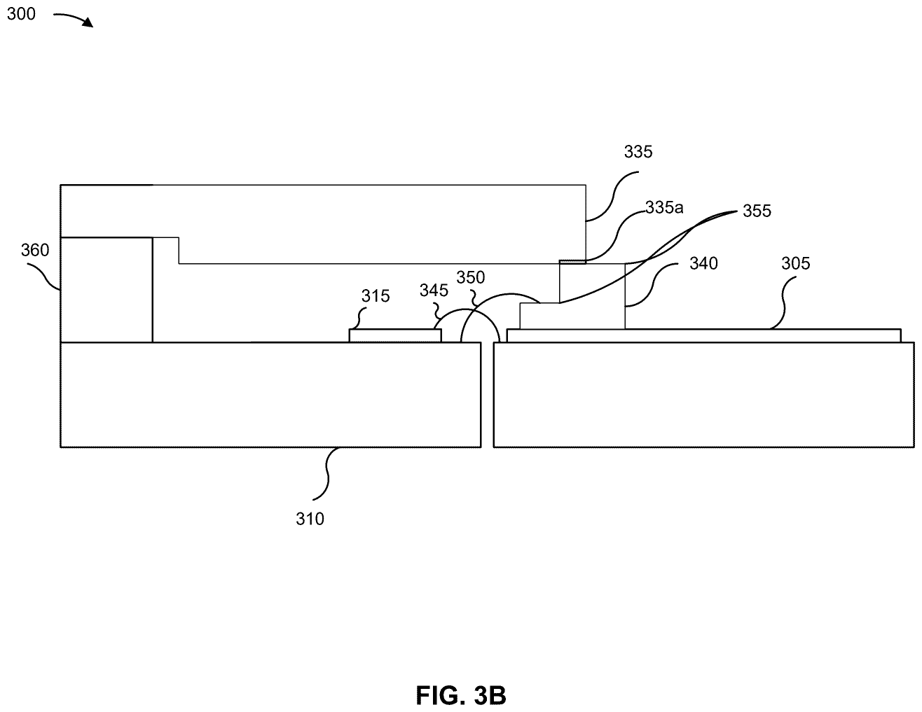

FIGS. 3A-3B are diagrams of an example implementation 300 associated with receiver shielding. As shown in FIGS. 3A-3B, example implementation 300 includes a PIC 305 and a receiver 310. The receiver 310 includes a set of receiver components 315, which may include one or more photodiodes or TIAs, among other examples. The set of receiver components 315 may connect to a receiver RF signal trace 320, which is disposed on a surface between receiver RF ground sections 325. In some implementations, a receiver shield 330 is disposed over the receiver 310. The receiver shield 330 may include a top cover 335 and a base 340, in some implementations. For example, the top cover 335 may be attached to the base 340 using an attachment 335a. The attachment 335a may include a glue, an epoxy, a mechanical attachment, or another attachment type. In some implementations, the top cover 335 may be attached to the base 340 using a conductive epoxy to provide a ground path. The base 340 may be positioned proximate to RF photodiode pads. By having a metallized structure with an RF interconnection to an RF ground of the receiver 310 via wire-bondings to a TIA region RF ground, as described herein, the base 340 provides RF shielding to the receiver 310 and couples field leakage from MZMs that are in proximity with the receiver 310. Furthermore, the top cover 335 may provide further reduction in field leakage coupling to the receiver 310. The top cover 335 may have a width that is based on a size of the receiver 310, such that the top cover 335 can shield an entirety of the receiver 310 and provide Tx-to-Rx crosstalk suppression.

In some implementations, one or more other structures may be present to form or support the receiver shield 330. For example, a standoff or glass block 360 may provide mechanical support to the receiver shield 330 and/or attach (e.g., epoxy) the receiver shield 330 to a package or housing of an optical device that includes the receiver 310 and the PIC 305. In this case, as shown, the glass block 360 mechanically supports the top cover 335 at an end of the receiver shield 330 that is distal to the base 340. Additionally, or alternatively, the top cover 335 may be disposed on a package or housing of an optical device that includes the receiver 310 and the PIC 305.

The top cover 335 is be disposed above the set of receiver components 315 and/or a portion of the receiver RF signal trace 320. Additionally, or alternatively, the base 340 may be disposed on the PIC 305. In some implementations, the base 340 may be offset from an edge of the PIC 305 to avoid a stress on the PIC 305. Additionally, or alternatively, the base 340 may be configured to be shorter than a length of the PIC 305 to avoid extending toward components at an edge of the PIC 305, such as to avoid being positioned at a fiber coupling of the PIC 305 (not shown). A first set of wire-bonds 345 may connect the set of receiver components 315 to the

PIC 305 and a second set of wire-bonds 350 may connect the receiver shield 330 (e.g., the base 340) to the receiver RF ground sections 325. In some implementations, the second set of wire-bonds 350 may include multiple wire-bonds. For example, the receiver shield 330 may connect to the receiver RF ground sections 325 via multiple wire-bonds, which may provide improved RF grounding relative to using a single wire-bond. In another example, the receiver shield 330 may connect to the receiver RF ground sections 325 at edges of the base 340, which may result in RF signal connections being surrounded by ground wire-bonds to the receiver shield 330. In some implementations, the wire-bonds may cover at least a portion of an RF component on the PIC 305 and/or the receiver 310.

In some implementations, the receiver shield 330 may be formed from a particular material. For example, the receiver shield 330 may be formed from a monolithic or layered metal structure, such as one or more aluminum layers. Additionally, or alternatively, the receiver shield 330 may be formed from a metallized structure, such as a glass (e.g., borosilicate glass) substrate material or a ceramic (aluminum nitride) substrate material that is metallized on one or more surfaces. In this case, metallization may be present on a top and/or a bottom surface of the receiver shield 330. Additionally, or alternatively, metallization may be omitted from some lateral sides of the receiver shield 330, which may improve manufacturability without significantly reducing crosstalk shielding.

In some implementations, the receiver shield 330 is associated with a stepped geometry or a shelf configuration. For example, as shown in FIG. 3B, and by reference number 355, the receiver shield 330 includes a stepped structure where the top cover 335 extends out from a first level of the base 340 and the wire-bonds 350 attach to a second level of the base 340. The stepped structure provides a surface (e.g., a shelf of the base 340 located under the top cover 335) onto which the second set of wire-bonds 350 can attach. In some implementations, the top cover 335 may be glued to a surface of the base 340 at attachment 335a (e.g., at a first level the stepped structure of base 340). The base 340 is attached to a top of the PIC 305 and wire bonded to the PIC 305, and the top cover 335 may be electrically connected to the base 340 (e.g., via a conductive surface) to ground the top cover 335 (e.g., via the base 340, the second set of wire-bonds 350, and the receiver RF ground sections 325).

As indicated above, FIGS. 3A-3B are provided as an example. Other examples may differ from what is described with regard to FIGS. 3A-3B.

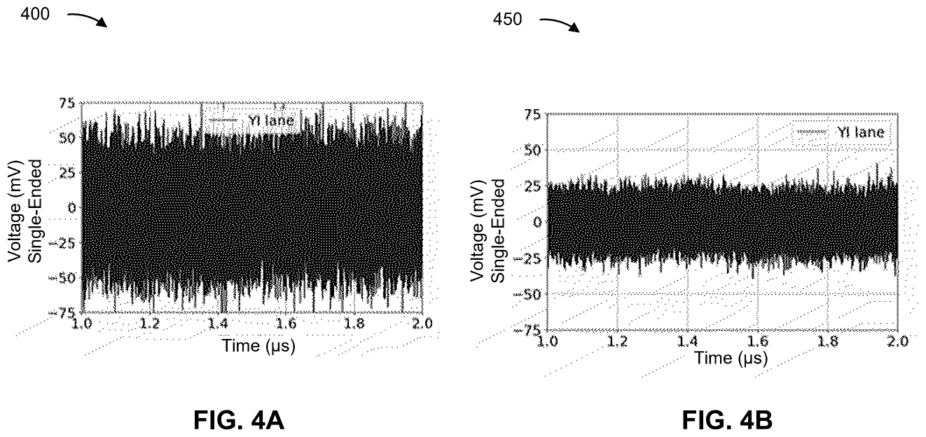

FIGS. 4A-4B are diagrams of crosstalk reduction associated with receiver shielding and transmitter shielding. As shown in FIGS. 4A, a first example 400 shows voltage measured in a receive lane when no signal is being received, but when a transmitter is on, resulting in Tx-to-Rx crosstalk. As shown in FIG. 4B, a second example 450 shows voltage measured in the receive lane when no signal is being received, but when the transmitter is on, but with Tx-to-Rx crosstalk being suppressed by a shield, such as a transmitter shield and a receiver shield disposed in an optical device. As shown in FIGS. 4A and 4B, a presence of a shield in an optical device results in a reduction in transmitter power that is coupled to a receiver. For example, in the first example 400, approximately 50 millivolts (mV) are coupled onto a receiver, but in the second example 450, approximately 25 mV are coupled onto a receiver. By reducing crosstalk, an optical device may achieve a lower error rate at the same input receiver power when the optical device includes a shield relative to when the optical device does not include a shield.

As indicated above, FIGS. 4A-4B are provided as an example. Other examples may differ from what is described with regard to FIGS. 4A-4B.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical device, comprising:
a transmitter,
wherein the transmitter includes a set of opto-electric modulators disposed on a first section of a photonic integrated circuit (PIC), and
wherein the transmitter includes a set of transmit (Tx) radio frequency (RF) electrical traces connected to the set of opto-electric modulators, the set of Tx RF traces including a first ground;
a receiver,
wherein the receiver is associated with a set of photodiodes, a set of trans-impedance amplifier (TIAs), and a set of receive (Rx) RF traces, wherein the set of RF traces is disposed on a second section of the PIC, the set of Rx RF traces including a second ground separate from the first ground,
a transmitter shield that is electrically connected to the first ground and includes a set of fingers on the PIC; and
a receiver shield partially on the PIC.

2. The optical device of claim 1, wherein the receiver shield includes a set of wire-bondings that electrically connect the receiver shield to the second ground.

3. The optical device of claim 1, wherein the receiver shield includes:
a base disposed on the PIC; and
a top cover extending over the base,
wherein the top cover is electrically connected to the base, and
wherein the top cover extends over at least one TIA, of the set of TIAs, and over at least a portion of at least one Rx RF trace of the set of Rx RF traces.

4. The optical device of claim 3, wherein the top cover extends over one or more wire-bonds between the PIC and the at least one TIA.

5. The optical device of claim 3, wherein the base includes a shelf, wherein the shelf is located under the top cover, and wherein the shelf is configured for receiving a wire bonding that electrically connects the receiver shield to the second ground.

6. The optical device of claim 3, wherein the top cover extends laterally beyond the base and the PIC.

7. The optical device of claim 3, wherein the top cover is mechanically supported at an end that is distal to the base.

8. The optical device of claim 3, wherein the transmitter shield includes a metallization element along a finger, of the set of fingers, adjacent to one or more opto-electric modulators of the set of opto-electric modulators.

9. An optical device, comprising:
a transmitter with a transmitter shield,
wherein the transmitter includes a set of opto-electric modulators disposed on a transmitter photonic integrated circuit (PIC),
wherein the transmitter includes a set of transmit (Tx) radio frequency (RF) electrical traces connected to the set of opto-electric modulators, the set of Tx RF traces including a first ground, and
wherein the transmitter shield includes a set of fingers on the PIC and wherein the transmitter shield is electrically connected to the first ground.

10. The optical device of claim 9, further comprising:
a receiver with a receiver shield,
wherein the receiver is associated with a set of photodiodes, a set of trans-impedance amplifiers (TIAs), and a set of receive (Rx) RF traces that are disposed on a receiver PIC, the set of Rx RF traces including a second ground separate from the first ground, and
wherein the receiver shield is partially on the PIC and electrically connected to the second ground.

11. The optical device of claim 10, wherein the transmitter shield is wire bonded to the first ground at a position within a threshold proximity of the receiver and on a same side of the PIC to which the set of TIAs is disposed.

12. The optical device of claim 9, wherein the transmitter shield includes a layer of metal disposed on at least one of a glass substrate material or a ceramic substrate material.

13. The optical device of claim 9, wherein one or more fingers, of the set of fingers, are adjacent to one or more opto-electric modulators of the set of opto-electric modulators.

14. The optical device of claim 9, wherein the set of fingers extend from a first end of the transmitter shield, the first end being at an interface between the set of Tx RF traces and the PIC.

15. The optical device of claim 14, wherein the set of fingers is electrically connected at a second end of the transmitter shield, the second end being distal from the first end of the transmitter shield.

16. The optical device of claim 9, wherein the set of fingers is disposed asymmetrically relative to the set of opto-electric modulators.

17. The optical device of claim 9, wherein a finger, of the set of fingers, is disposed closer to a ground trace than to a signal trace associated with a corresponding opto-electric modulator of the set of opto-electric modulators.

18. The optical device of claim 9, wherein a finger, of the set of fingers, is wire bonded to the first ground at an interface between the set of Tx RF traces and the PIC.

19. An optical device, comprising:
a transmitter, comprising:
a set of opto-electric modulators disposed on a first photonic integrated circuit (PIC),
a set of transmit (Tx) radio frequency (RF) electrical traces connected to the set of opto-electric modulators, the set of Tx RF traces including a first ground;
a receiver, comprising:
a set of receive (Rx) RF traces disposed on a second PIC, the set of Rx RF traces including a second ground separate from the first ground;
a transmitter shield on the first PIC and electrically connected to the first ground; and
a receiver shield partially on the second PIC and electrically connected to the second ground.

20. The optical device of claim 19, wherein the first PIC and the second PIC are disposed on a single chip substrate.
